(19) United States
(12) Patent Application Publication
(10) Pub. No.: US 2025/0279745 A1
(43) Pub. Date: Sep. 4, 2025

(54) Responsive Colored Facades and Methods of Use

(71) Applicant: The Board of Regents of the University of Oklahoma, Norman, OK (US)

(72) Inventors: Negar Heidari Matin, Norman, OK (US); Zhina Rashidzadeh, Norman, OK (US)

(73) Assignee: The Board of Regents of the University of Oklahoma, Norman, OK (US)

(21) Appl. No.: 19/068,868

(22) Filed: Mar. 3, 2025

Related U.S. Application Data
(60) Provisional application No. 63/560,244, filed on Mar. 1, 2024.
(60) Provisional application No. 63/691,618, filed on Sep. 6, 2024.
(60) Provisional application No. 63/721,313, filed on Nov. 15, 2024.

(51) Int. Cl. H02S 20/32; H02S 30/10; H10F 77/30

(52) U.S. Cl. CPC H02S 20/32; H02S 30/10; H10F 77/311

(57) ABSTRACT

A responsive façade system is configured to control the transmission of light from a first side of the responsive façade system to a second side of the responsive façade system in response to inputs from one or more light sensors. The responsive façade system includes a drive system, a plurality of panels driven by the drive system, and a control system. The control system is configured to send drive signals to the drive system to rotate the plurality of panels to selectively block the amount of light passing from the first side of the responsive façade system to the second side of the responsive façade system. In some applications, the light sensors are configured to measure real-time sunlight data such that the control system can instruct the drive system to rotate one or more of the plurality of panels into a position based on the real-time sunlight data.

### RELATED APPLICATIONS

This application claims the benefit of U.S. Provisional Patent Application Ser. No. 63/560,244 filed Mar. 1, 2024 entitled, “Responsive Colored Facades and Methods of Use,” U.S. Provisional Patent Application Ser. No. 63/691,618 filed Sep. 6, 2024 entitled, “Responsive Colored Facades and Methods of Use,” and U.S. Provisional Patent Application Ser. No. 63/721,313 filed Nov. 15, 2024 also entitled “Responsive Colored Facades and Methods of Use,” the disclosures of which are each incorporated by reference as if fully set forth herein, including any appendices filed with these provisional patent applications.

### BACKGROUND

Responsive façade systems are internal or external architectural features that are capable of changing in response to stimuli, including temperature, sunlight and other conditions. Responsive facade systems have been classified into five different categories based on the types of control, sensing, and actuating technologies used in the systems. These include mechanical technology, electro-mechanical technology, passive technology, information technology, and advanced material technology. There are multiple responsive facade examples that are operated using any of these technology categories individually. These implemented technologies have their benefits, and shortcomings, which can be compared in order to identify the reasons for utilizing a specific technology in facades. Each category of technology has advantages, but there is no integrated technology that combines the advantages of the various technologies with the goal of achieving better efficiency through advanced responsive facades. It is to these and other deficiencies in the prior art that the present disclosure is directed.

### BRIEF DESCRIPTION OF THE DRAWINGS

For a more complete understanding of this disclosure, reference is now made to the following brief description, taken in connection with the accompanying drawings and detailed description, wherein like reference numerals represent like parts. The figures are not necessarily to scale and certain features and certain views of the figures may be shown as exaggerated in scale or in schematic in the interest of clarity and conciseness. The patent or application file contains at least one drawing executed in color. Copies of this patent or patent application publication with color drawing(s) will be provided by the Office upon request and payment of the necessary fee.

FIG. 1 shows a generalized version of the disclosed responsive facade system.

FIG. 2 depicts the responsive façade system of FIG. 1 with elements of the frame assembly removed with the panels rotated into a light obstructive state.

FIGS. 3A-3C depict a first embodiment of a panel from the responsive façade system of FIG. 1 in various rotational states.

FIGS. 4A-4C depict a second embodiment of a panel from the responsive façade system of FIG. 1 in various rotational states.

FIG. 5 depicts the responsive façade system of FIG. 2 with the panels rotated into a light transmissive state.

FIG. 6 depicts an embodiment of the responsive façade system in which each of the individual panels includes a unique motor.

FIG. 7 depicts an embodiment of the responsive façade system deployed on a south-facing wall in a light transmissive state providing early morning sunlight into an interior space.

FIG. 8 depicts the responsive façade system of FIG. 7 in which the responsive façade system has shifted to a light restrictive state to limit the amount of sunlight entering the interior space during late morning.

FIG. 9 depicts the responsive façade system of FIG. 7 in which the responsive façade system has shifted to a light obstructive state to significantly limit the amount of sunlight entering the interior space during mid-afternoon.

FIG. 10 depicts the responsive façade system of FIG. 7 in which the responsive façade system has shifted back to a light restrictive state to limit the amount of sunlight entering the interior space during late afternoon.

FIG. 11 depicts the responsive façade system of FIG. 7 in which the responsive façade system has shifted to a light transmissive state to permit sunlight to enter the interior space during early evening.

FIG. 12 depicts the responsive façade system of FIG. 2 in which a first set of the panels have been rotated into a light transmissive state while a second set of the panels has been rotated into a light obstructive state.

FIG. 13 presents the rotational degrees for the PAC model.

FIG. 14 provides a comparison of two embodiments of the responsive façade system with a benchmark luminance.

FIG. 15 depicts the daytime glare probability (DGP) for the PAC and PAI models during March.

FIG. 16 depicts the daytime glare probability (DGP) for the PAC and PAI models during September.

### DETAILED DESCRIPTION

The present disclosure is directed to light-responsive colored facades constructed as a hybrid system based on integrated electro-mechanical and advanced material technologies. In particular, the light-responsive colored facade is a system which is able to adapt to changing daylight patterns, taking into account the intensity and direction of sunlight. The visual performance of this system was evaluated using a data-driven approach, considering different design scenarios such as various facade configurations, orientations, and locations/climate zones. The evaluation of the visual performance demonstrated that the disclosed system can enhance the visual comfort of individuals within the building. The novel hybrid control technology of the presently disclosed system provides enhanced efficiency, flexibility in design, controllability, responsiveness, individuality, and variability in control systems.

Before further describing various embodiments of the apparatus, component parts, and methods of the present disclosure in more detail by way of exemplary description, examples, and results, it is to be understood that the embodiments of the present disclosure are not limited in application to the details of apparatus, component parts, and methods as set forth in the following description. The embodiments of the apparatus, component parts, and methods of the present disclosure are capable of being practiced or carried out in various ways not explicitly described herein. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting unless otherwise indicated as so. Moreover, in the following detailed description, numerous specific details are set forth in order to provide a more thorough understanding of the disclosure. However, it will be apparent to a person having ordinary skill in the art that the embodiments of the present disclosure may be practiced without these specific details. In other instances, features which are well known to persons of ordinary skill in the art have not been described in detail to avoid unnecessary complication of the description. While the apparatus, component parts, and methods of the present disclosure have been described in terms of particular embodiments, it will be apparent to those of skill in the art that variations may be applied to the apparatus, component parts, and/or methods and in the steps or in the sequence of steps of the method described herein without departing from the concept, spirit, and scope of the inventive concepts as described herein. All such similar substitutes and modifications apparent to those having ordinary skill in the art are deemed to be within the spirit and scope of the inventive concepts as disclosed herein.

All patents, published patent applications, and non-patent publications referenced or mentioned in any portion of the present specification are indicative of the level of skill of those skilled in the art to which the present disclosure pertains, and are hereby expressly incorporated by reference in their entirety to the same extent as if the contents of each individual patent or publication was specifically and individually incorporated herein.

Unless otherwise defined herein, scientific and technical terms used in connection with the present disclosure shall have the meanings that are commonly understood by those having ordinary skill in the art. Further, unless otherwise required by context, singular terms shall include pluralities and plural terms shall include the singular.

As utilized in accordance with the methods and compositions of the present disclosure, the following terms and phrases, unless otherwise indicated, shall be understood to have the following meanings: The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or when the alternatives are mutually exclusive, although the disclosure supports a definition that refers to only alternatives and “and/or.” The use of the term “at least one” will be understood to include one as well as any quantity more than one, including but not limited to, 2, 3, 4, 5, 6, 7, 8, 9, 10, 15, 20, 30, 40, 50, 100, or any integer inclusive therein. The phrase “at least one” may extend up to 100 or 1000 or more, depending on the term to which it is attached; in addition, the quantities of 100/1000 are not to be considered limiting, as higher limits may also produce satisfactory results. In addition, the use of the term “at least one of X, Y and Z” will be understood to include X alone, Y alone, and Z alone, as well as any combination of X, Y and Z.

As used in this specification and claims, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Throughout this application, the terms “about” or “approximately” are used to indicate that a value includes the inherent variation of error for the composition, the method used to administer the composition, or the variation that exists among the study subjects. As used herein the qualifiers “about” or “approximately” are intended to include not only the exact value, amount, degree, orientation, or other qualified characteristic or value, but are intended to include some slight variations due to measuring error, manufacturing tolerances, observer error, and combinations thereof, for example. The term “about” or “approximately”, where used herein when referring to a measurable value such as an amount, a temporal duration, and the like, is meant to encompass, for example, variations of ±20% or ±10%, or ±5%, or ±1%, or ±0.1% from the specified value, as such variations are appropriate to perform the disclosed methods and as understood by persons having ordinary skill in the art. As used herein, the term “substantially” means that the subsequently described event or circumstance completely occurs or that the subsequently described event or circumstance occurs to a great extent or degree. For example, the term “substantially” means that the subsequently described event or circumstance occurs at least 80% of the time, at least 90% of the time, at least 91% of the time, at least 92% of the time, at least 93% of the time, at least 94% of the time, at least 95% of the time, at least 96% of the time, at least 97% of the time, at least 98% of the time, or at least 99% of the time.

Where used herein, the pronoun “we” is intended to refer to all persons involved in a particular aspect of the investigation disclosed herein and as such may include non-inventor laboratory assistants and non-inventor collaborators working under the supervision of the inventor(s).

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

As used herein, all numerical values or ranges include fractions of the values and integers within such ranges and fractions of the integers within such ranges unless the context clearly indicates otherwise. Thus, to illustrate, reference to a numerical range, such as 1-10 includes 1, 2, 3, 4, 5, 6, 7, 8, 9, 10, as well as 1.1, 1.2, 1.3, 1.4, 1.5, etc., and so forth. Reference to a range of 1-50 therefore includes 1, 2, 3, 4, 5, 6, 7, 8, 9, 10, 11, 12, 13, 14, 15, 16, 17, 18, 19, 20, etc., up to and including 50, as well as 1.1, 1.2, 1.3, 1.4, 1.5, etc., 2.1, 2.2, 2.3, 2.4, 2.5, etc., and so forth. Reference to a series of ranges includes ranges which combine the values of the boundaries of different ranges within the series. Thus, to illustrate reference to a series of ranges, for example, a range of 1-1,000 includes, for example, 1-10, 10-20, 20-30, 30-40, 40-50, 50-60, 60-75, 75-100, 100-150, 150-200, 200-250, 250-300, 300-400, 400-500, 500-750, 750-1,000, and includes ranges of 1-20, 10-50, 50-100, 100-500, and 500-1,000. The range 100 units to 2000 units therefore refers to and includes all values or ranges of values of the units, and fractions of the values of the units and integers within said range, including for example, but not limited to 100 units to 1000 units, 100 units to 500 units, 200 units to 1000 units, 300 units to 1500 units, 400 units to 2000 units, 500 units to 2000 units, 500 units to 1000 units, 250 units to 1750 units, 250 units to 1200 units, 750 units to 2000 units, 150 units to 1500 units, 100 units to 1250 units, and 800 units to 1200 units. Any two values within the range of about 100 units to about 2000 units therefore can be used to set the lower and upper boundaries of a range in accordance with the embodiments of the present disclosure. More particularly, a range of 10-12 units includes, for example, 10, 10.1, 10.2, 10.3, 10.4, 10.5, 10.6, 10.7, 10.8, 10.9, 11.0, 11.1, 11.2, 11.3, 11.4, 11.5, 11.6, 11.7, 11.8, 11.9, and 12.0, and all values or ranges of values of the units, and fractions of the values of the units and integers within said range, and ranges which combine the values of the boundaries of different ranges within the series, e.g., 10.1 to 11.5.

As noted above, any numerical range listed or described herein is intended to include, implicitly or explicitly, any number or sub-range within the range, particularly all integers, including the end points, and is to be considered as having been so stated. For example, “a range from 1.0 to 10.0” is to be read as indicating each possible number, including integers and fractions, along the continuum between and including 1.0 and 10.0, that is, having a minimum value equal to or greater than 1.0 and a maximum value equal to or less than 10.0, such as, for example, 3.25 to 8.65. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. Thus, even if a particular data point within the range is not explicitly identified or specifically referred to, it is to be understood that any data points within the range are to be considered to have been specified, and that the inventor(s) possessed knowledge of the entire range and the points within the range.

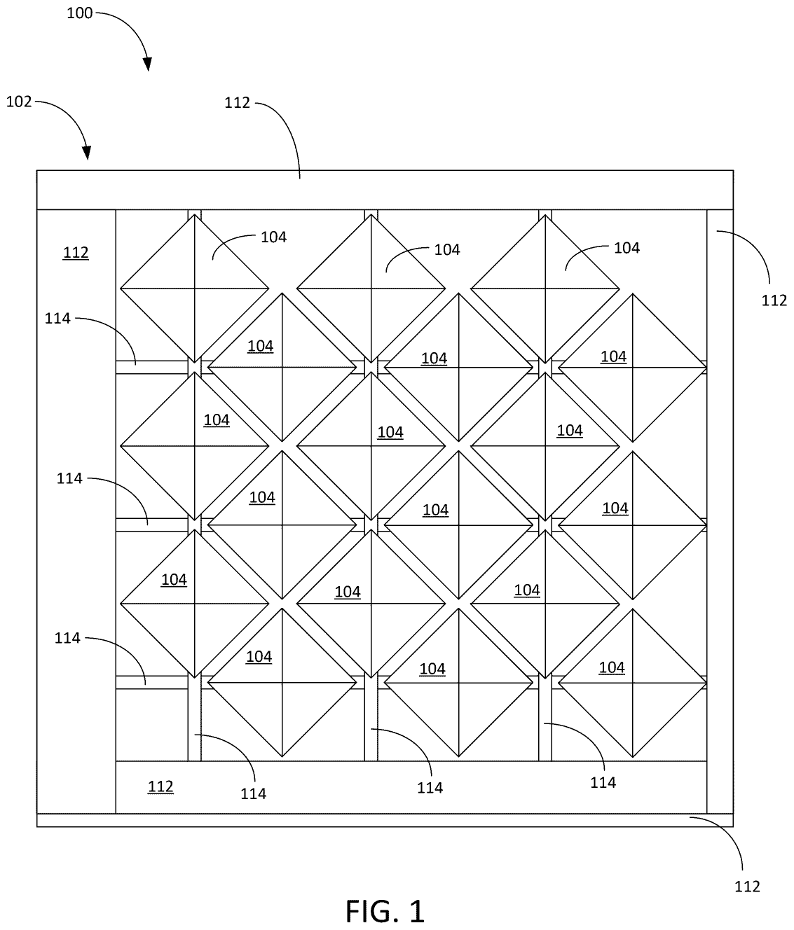

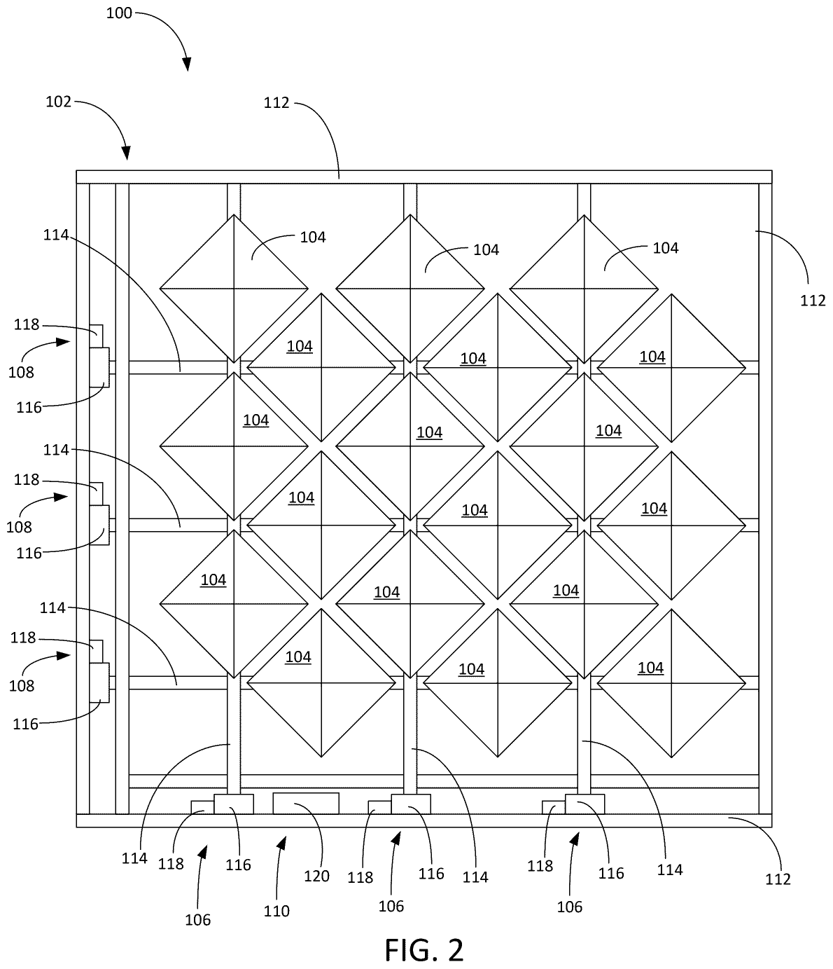

Turning to FIGS. 1 and 2, shown therein is an embodiment of a responsive façade system 100 that is capable of installation and operation inside or outside of a building or other structure. The responsive façade system 100 includes a frame assembly 102, a plurality of panels 104, a drive system 106, one or more sensors 108 and one or more control systems 110. The frame assembly 102 includes a plurality of interconnected frame members 112 that support the panels 104. In some embodiments, the frame assembly 102 is integrated into an internal or external wall or sill of a building or other structure. In many installations, the responsive façade system 100 is positioned in front of or behind a window or a plurality of windows. Portions of the frame assembly 102 have been removed in FIG. 2 to reveal components of the responsive façade system 100 located inside the frame assembly 102.

The drive system 106 is configured to support and orient the plurality of panels 104 in response to drive signals produced by the control system 110. The drive system 106 includes a plurality of carriers 114 and drive motors 116. The carriers 114 support the panels 104. The carriers 114 include horizontally oriented carriers 114 and vertically oriented carriers 114. It will be appreciated that in other embodiments the carriers 114 are oriented in non-vertical and non-horizontal orientations. In some embodiments, the carriers 114 are shafts or rods that are manufactured from plastic, metal or composite materials and capable of supporting one or more panels 104.

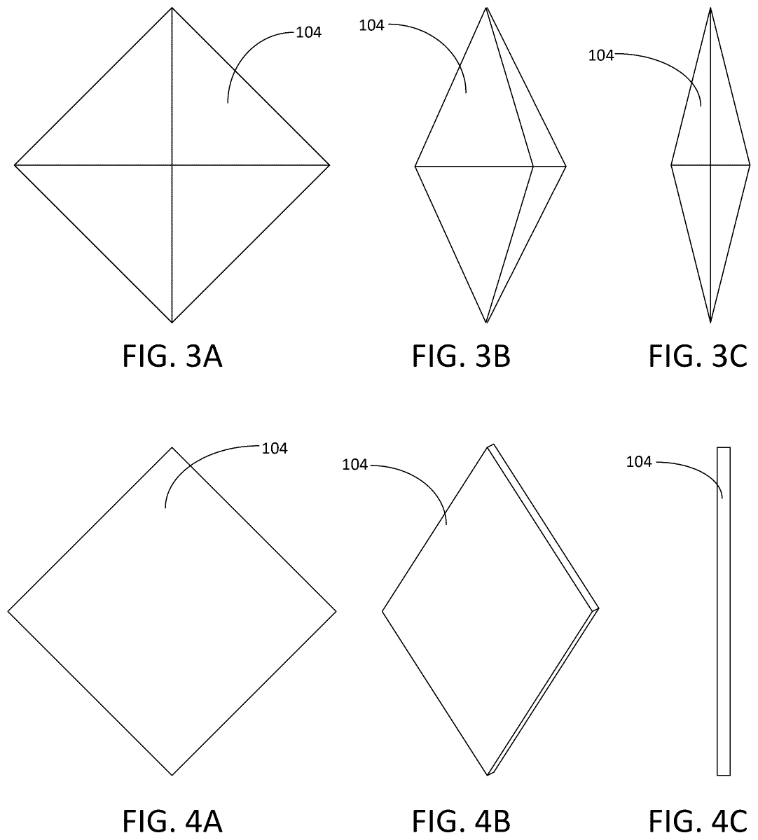

FIGS. 3A-3C depict a panel 104 constructed in accordance with a first embodiment in which the panel 104 approximates an octahedron that can be rotated along a central horizontal or central vertical axis to change the area of the effective face from a maximum (FIG. 3A) to an intermediate (FIG. 3B) to a minimum (FIG. 3C). FIGS. 4A-4C depict a panel 104 constructed in accordance with a second embodiment in which the panel 104 approximates a closed box or rectangular prism that can also be rotated along a central horizontal or vertical axis to change the area of the effective face from a maximum (FIG. 4A) to an intermediate (FIG. 4B) to a minimum (FIG. 4C). It will be appreciated that the panels 104 depicted in FIGS. 3A-4C are non-limiting examples and the panels 104 can also take other shapes and sizes. In some embodiments, the responsive façade system 100 includes panels 104 having a variety of shapes and sizes, which may be helpful in maximizing the coverage provided by the panels 104 within the responsive façade system 100.

In some embodiments, the panels 104 are manufactured from plastic, lightweight metal or composite materials. Some or all of the panels 104 within the responsive façade system 100 can be coated with photochromic materials to automatically adjust light transmissibility in response to the intensity of light striking the panels 104 within a range from transparency or translucence to opacity. In some embodiments, one or more of the panels 102 are tinted, painted, or covered with membranes to produce opacity, translucence or colored faces. In some embodiments, one or more of the panels 104 include light emitting components. In some embodiments, one or more of the panels 104 includes a photovoltaic coating or photovoltaic module that produces electricity in response to light striking the photovoltaic element on the panel 104.

The sensor system 108 includes one or more light sensors 118 that measure the amount of light at various locations within the responsive façade system 100 or at a location spaced apart from the responsive façade system 100. The light sensors 118 output a light intensity signal to the control system 110. In some embodiments, the light sensors 118 are located near the drive motors 116, while in other embodiments the light sensors 118 are located on the panels 104. The light sensors 118 can communicate with the control system 110 through a wired or wireless connection.

The sensor system 108 can also include other types of sensors such as humidity sensors, temperature sensors, wind sensors, moisture sensors, audible noise sensors, and radiation sensors.

The control system 110 includes a processor or controller 120 configured to produce drive signals to the drive motors 116 in response to inputs from the sensor system 108. Although the controller 120 is depicted as a standalone module in FIG. 2, it will be appreciated that the controller 120 can be incorporated into a climate control system or other computing system. The control system 110 can also be configured to adjust the operation of the drives system 106 based on the time of day and the time of year, or in response to inputs from human operators and automated climate control systems.

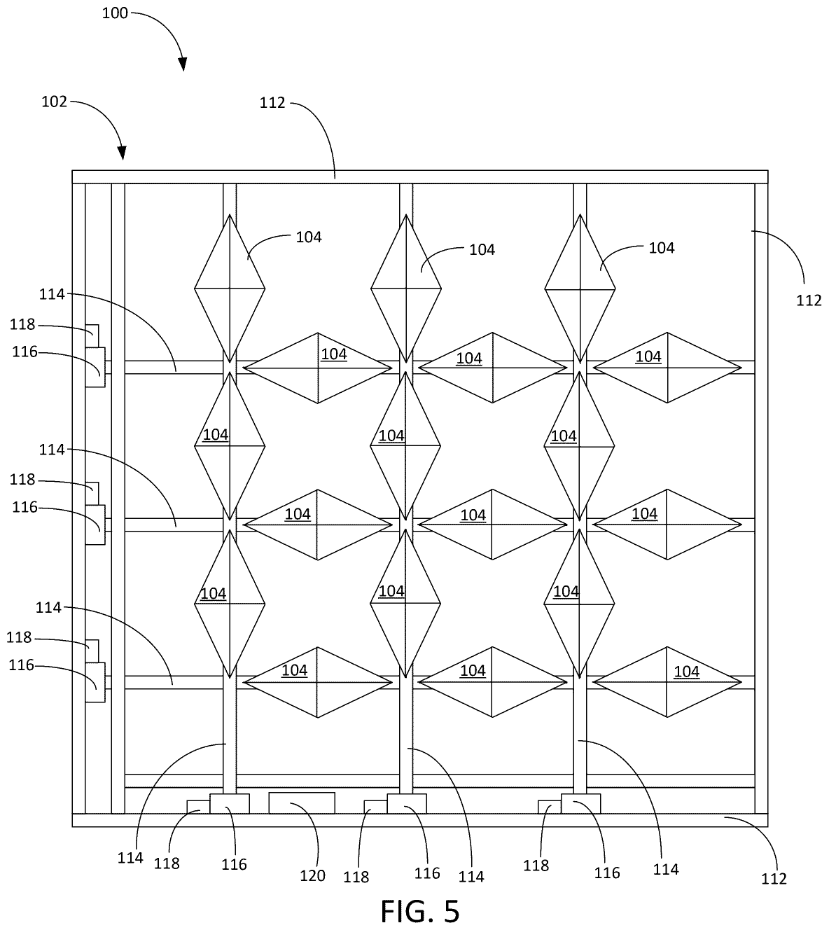

In the embodiment depicted in FIGS. 2 and 5, each carrier 114 is connected to a corresponding drive motor 116, which is configured to selectively rotate the carrier 114 and the connected panels 104. Each drive motor 116 is secured to the frame assembly 102 and coupled to the corresponding carriers 114. Rotating the carrier 114 causes the rotation of all of the panels 104 connected to the carrier 114, as depicted in FIG. 5. Thus, the control system 110 is configured to change the responsive façade system 100 from a light restrictive state (FIG. 2) to a light transmissive state (FIG. 5) by rotating the carriers 114 by about 90 degrees, depending on the geometry and configuration of the panels 104. As illustrated in FIG. 12, the control system 110 can rotate a subset of the carriers 114 and panels 104 to permit the increased transmission of light through a portion of the full responsive façade system 100. This may be helpful in applications in which it is desirable to focus light on a portion of the interior space rather than controlling the intensity of light throughout the entire interior space. The embodiment depicted in FIGS. 2 and 5 can be referred to as a “passive active cluster” or “PAC” in which the panels 104 include a passive light blocking feature (like a photochromic material coating) and the panels 104 are rotated in groups or “clusters” to adjust the effective blocking area presented by the panels 104.

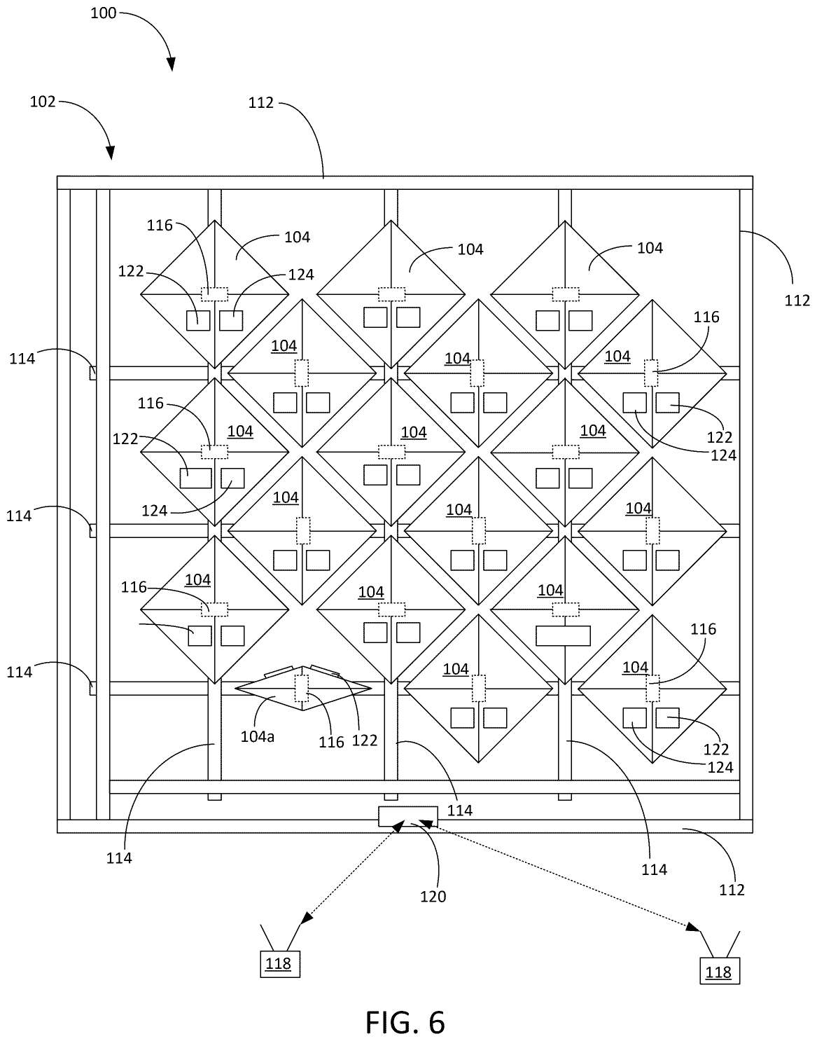

Turning to FIG. 6, shown therein is an embodiment in which each panel 104 can be independently controlled and rotated. In this embodiment, a separate drive motor 116 is connected between each panel 104 and the corresponding carrier 114, which can remain stationary. Energizing the drive motor 116 causes the corresponding panel 104 to rotate about the stationary carrier 114. Panel 104a has been rotated into a light transmissive state while the remaining panels 104 remain in a light obstructive state. In the embodiment depicted in FIG. 6, at least some of the panels 104 include a photovoltaic module 122 that produces electricity, which can be stored in an onboard battery 124 connected to the drive motor 116. This may obviate the need for wires between the control system 110 and drive motors 116. The drive motors 116 can be connected to the controller 120 through a wired or wireless connection. The embodiment depicted in FIG. 6 can be referred to as a “passive active individual” or “PAI,” in which one or more of the panels 104 includes a passive light blocking feature (like a photochromic material coating) and can be rotated independently of the other panels 104 to adjust the effective blocking area presented by the “individual” panel 104. It will be appreciated that in certain embodiments, the responsive façade system 100 includes a combination of panels 104 arranged as passive active clusters and panels 104 arranged as passive active individuals.

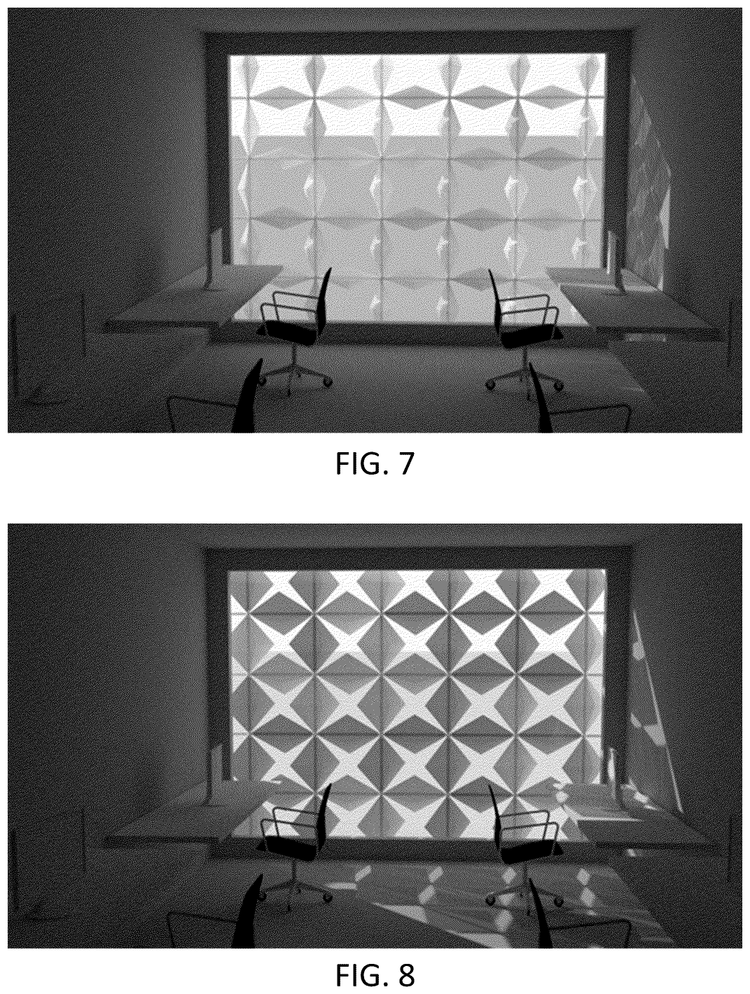

Turning to FIGS. 7-11, shown therein is an installation of an embodiment of the responsive façade system 100 in which the responsive façade system 100 is used to control the amount of sunlight entering an interior space. The responsive façade system 100 has been installed on a south-facing wall of a building. FIG. 7 depicts the responsive façade system 100 in a light transmissive state to allow sunlight to enter the interior space shortly after dawn. In FIG. 7, the panels 104 are rotated to maximize the transmission of light into the interior space. As the day progresses and the intensity of the sunlight increases, the responsive façade system 100 shifts to a light restrictive state by rotating some or all of the panels 104 to a partially obstructive orientation, as depicted in FIG. 8.

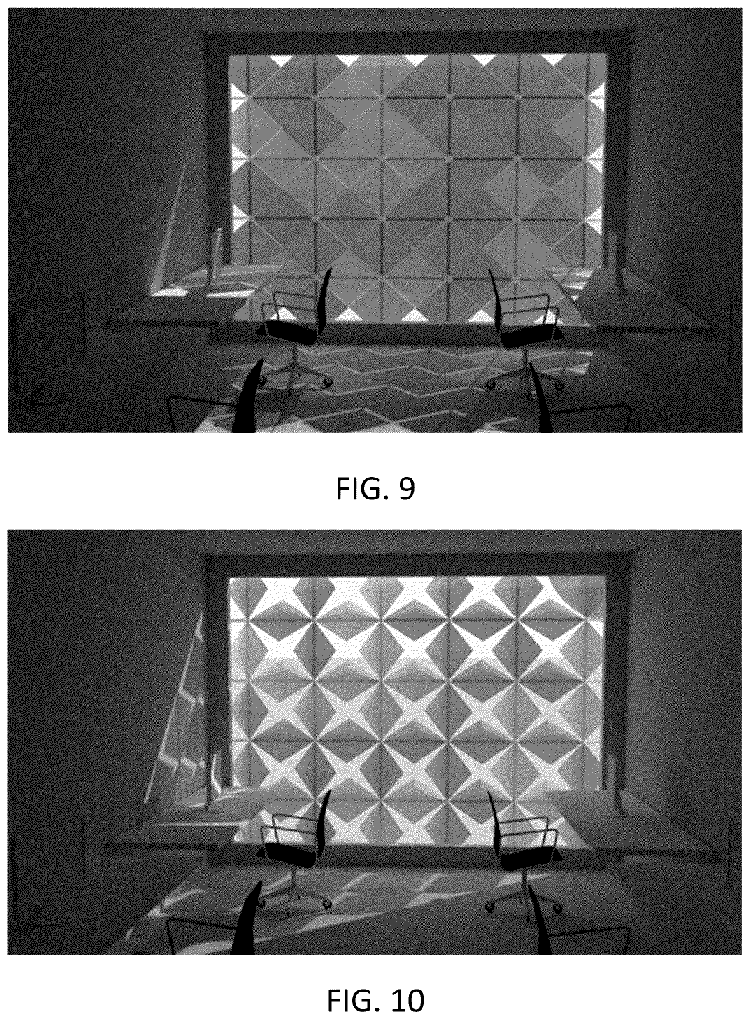

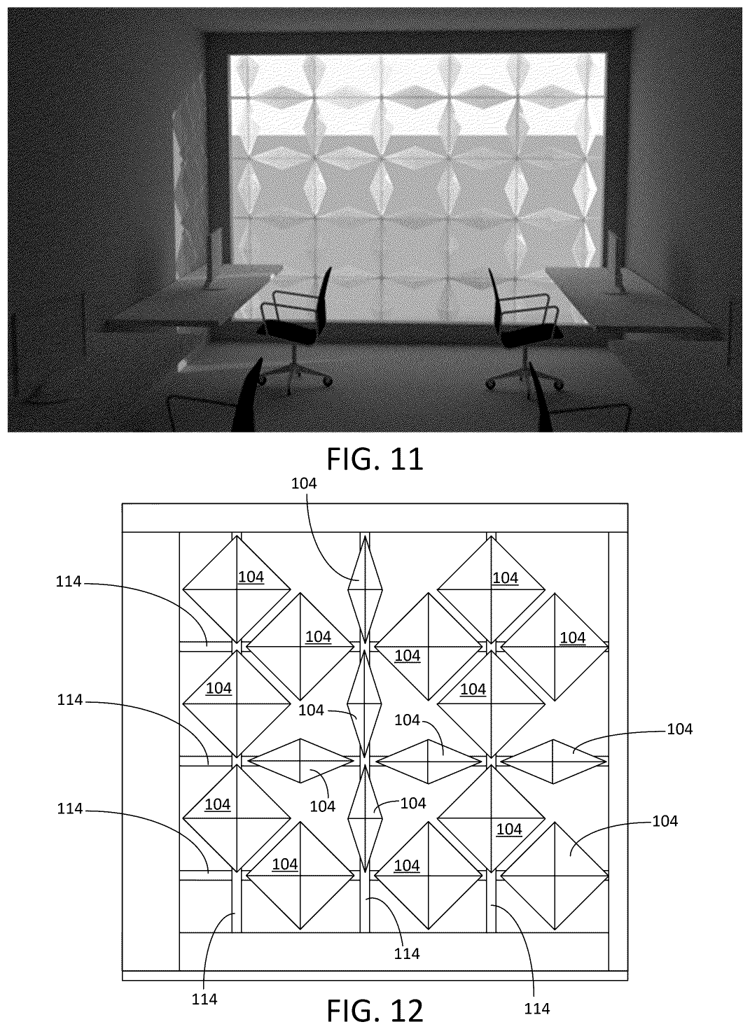

FIG. 9 depicts the responsive façade system 100 in a light obstructive state in which the panels 104 have been rotated to minimize the transmission of sunlight into the interior space during the brightest part of the day. In FIG. 10, the sun is beginning to set and the lower light intensity levels-whether measured directly by the sensor system 108 or indirectly as a function of the time of day-cause the control system 110 to shift the responsive façade system 100 into a light restrictive state in which the panels 104 permit more light to enter the interior space. FIG. 11 depicts the responsive façade system 100 after shifting back to a light transmissive state during early evening to permit additional light into the interior space. Thus, the responsive façade system 100 is well-suited for controlling the amount of sunlight entering the interior space throughout the day and across changing conditions during the year. The responsive façade system 100 can be configured to automatically adjust the orientation, color transparency and color spectrum of the panels 104 in response to predicted or detected sunlight patterns, sunlight intensity, and sunlight direction.

In addition to automatically controlling the amount of light passing into the interior space, the responsive façade system 100 can also be used to provide privacy for the interior space by shifting the responsive façade system 100 to the light obstructive state. Additionally, the responsive façade system 100 can be controlled in a variety of sequences to create appealing or interesting visual effects. For example, the panels 104 can be rotated in sequences that create pulsating or wavelike movements.

The responsive façade system 100 optimizes illuminance levels based on luminance levels on the window by combining the characteristics of photochromic glass with a kinetic responsive system to achieve improved visual comfort compared to the conventional facade. Simulations were run to test the effectiveness of various embodiments of the responsive façade system 100. Various metrics such as daylight glare probability (DGP), illuminance, and luminance were evaluated using computer-implemented modeling software. According to the DGP equation (Equation 1), glare is influenced by the luminance of the window, the angle of the lighting source (e.g., the sun), and illuminance. To enhance visual comfort based on DGP, the presented hybrid facade is designed to regulate these factors. In the Equation 1, Eᵥ is the vertical illuminance of the observer's eye, L_{s,i} is the luminance of the glare source, ω_{s,i} is the solid angle of the light source and, Pᵢ is the position index of the occupant's eye.

$$DGP = 5.87 \times {10}^{- 5} \times {E}_{v} + 9.18 \times {10}^{- 5} log ( 1 + {\sum }_{i} \frac{{L}_{s , i}^{2}}{{E}_{F}^{1.87}} \frac{{ω}_{s , i}}{{P}_{i}^{2}} ) + 0.16 \qquad ( 1 )$$

The responsive façade system 100 enhances visual comfort by actuating individual panels 104 (PAI) or groups of panels 104 (PAC) to adjust the luminance of the window. By locating areas of excess luminance on windows and covering them with panels 104, the responsive façade system 100 reduces DGP while maintaining adequate illuminance. In exemplary embodiments, the responsive façade system 100 is controlled or programmed for automatic operation to block excess light on some points of the window, while allowing useful daylight to enter through other points of the window without permitting excess light to pass through the window.

For the simulation, the panels 104 were created using photochromic-coated glass to achieve passive responsiveness. The photochromic panel 104 were operated using both cluster movement (PAC) and individual movement (PAI). In the PAC system, all panels 104 rotate in a cluster while in the PAI mechanism, each panel 104 rotates individually. The resulting data was analyzed, and compared, and conclusions were drawn.

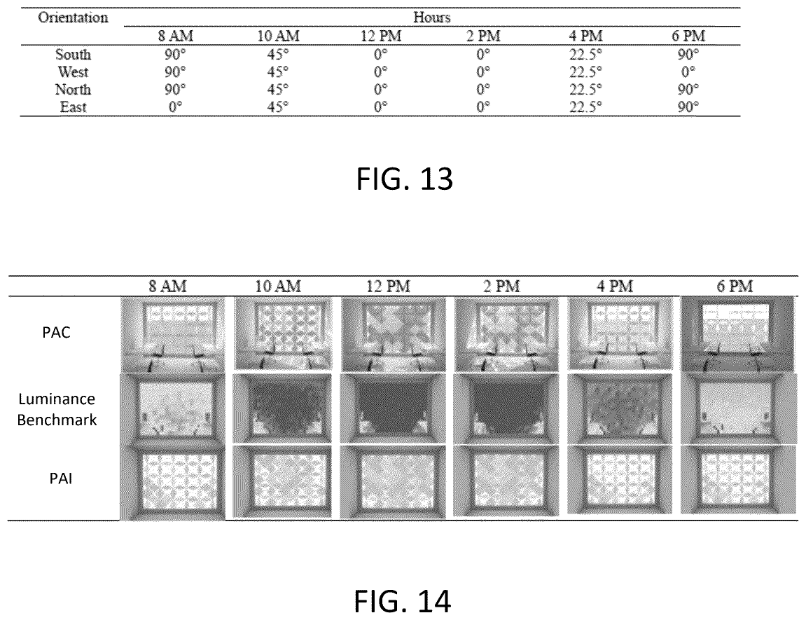

To evaluate the performance of the responsive façade system 100 using the PAI and PAC control systems, a regular window without any shading was simulated and defined as the benchmark. The benchmark and PAC facade model underwent illuminance, luminance, and DGP simulations from 8 AM to 6 PM for a day on the 21st of each month during the 12 months. Meanwhile, the PAI model underwent similar simulations during the solstice and equinox months. In these simulations, the angles of the panels 104 were treated as the independent variables to evaluate their impact on visual performance metrics. Visual comfort metrics simulations were conducted for a building with four orientations including South, West, North, and East in benchmark, PAC, and PAI facade models. In the PAC scenario, each carrier 114 rotates separately toward the sun to put the panels 104 in different positions based on the window surface at different hours of the day in different building orientations. To determine the rotational degrees in each hour, DGP for five stages including fully open (90 degrees), partially open (67.5 degrees), semi-open (45 degrees), partially closed (22.5 degrees), and closed (0 degrees) was simulated during October which demonstrates highest DGP among other months. The best transitional degree in each hour was chosen for further simulations in a way that the responsive façade system 100 goes from open to close and to open from morning to noon to evening. The rotational degrees for the PAC model are shown in FIG. 13. The PAI model included 41 panels 104, each of them rotating individually to cover the points on the window that exceeds 60 cd/m2 based on luminance simulations. A comparison of the PAC model, the PAI model and the benchmark model are presented in FIG. 14.

The simulations and corresponding analysis involved comparing the DGP, illuminance, and luminance results of the benchmark, PAC, and PAI models, determining the respondent degree for the PAI based on the illuminance data in the comfort threshold standards, and establishing the most effective illuminance comfort standard in relation to DGP and luminance. A comprehensive analysis was made of the DGP, illuminance, and luminance data for the benchmark, PAC, and PAI models.

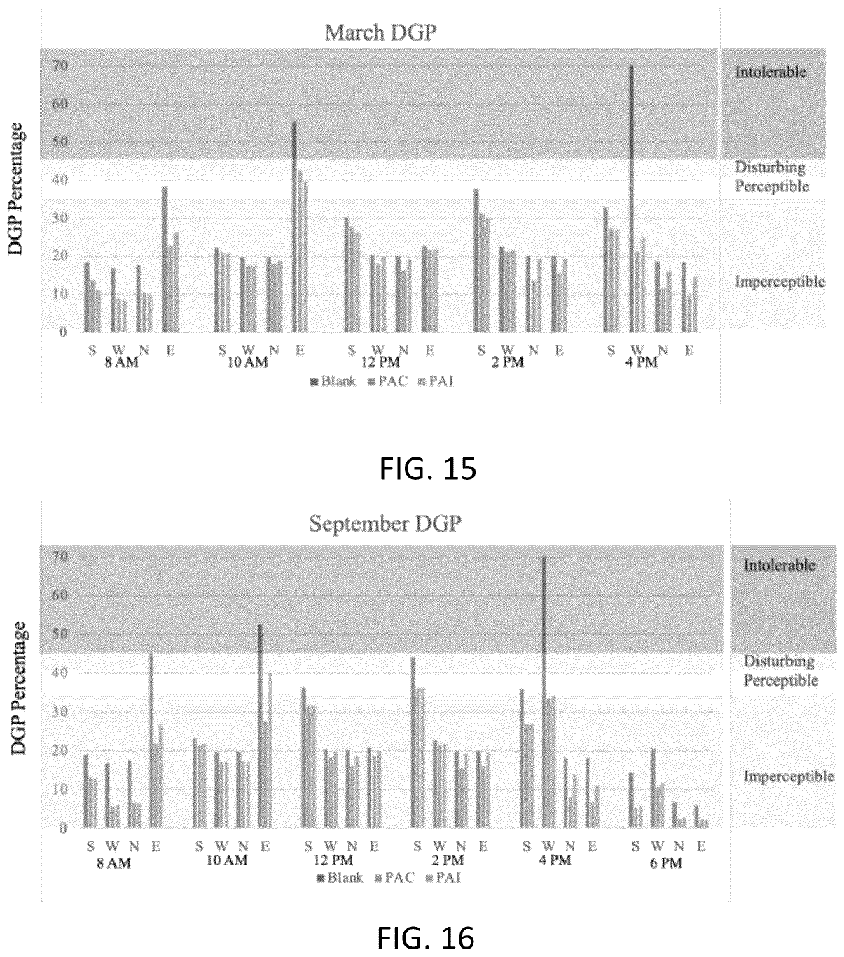

The DGP data visualizations (FIGS. 15-16) establish that the PAC model of the responsive façade system 100 greatly decreases DGP all year round, regardless of the time of day. Specifically, DGP remains consistently within the acceptable range, while the benchmark exhibits unacceptable levels of DGP for a significant number of piles. Additionally, the PAI model of the responsive façade system 100 reduces DGP across all data points, with 83 DGP outcomes in the imperceptible, 6 in the perceptible, and 2 in the disturbing, out of a total of 91 DGP data points. Moreover, 74 DGP outcomes for the benchmark and 87 DGP data for the PAC were in the imperceptible zone, 4 for the benchmark and 2 for PAC were in the perceptible zone, 3 for the benchmark, and 2 for the PAC were in the disturbing zone. While PAC and PAI did not have any intolerable glare, using the benchmark resulted in 10 data points in the intolerable range.

The novel responsive façade system 100 can be implemented across both commercial and residential building facades, thereby providing privacy, enhancing visual comfort, diminishing energy consumption, and reducing artificial lighting within buildings. The responsive façade system 100 is scalable and amenable to large-scale production as prefabricated panels, suitable for incorporation into building facades during or after construction. Various architectural and construction entities can adopt the responsive façade system 100 to inform the design and assembly of their building's façades, with the flexibility to customize the coating materials in accordance with individual predilections. Importantly, the responsive façade system 100 combines an advanced control system 110, sensor system 108, and drive system 106 with panels 104 that have been manufactured with advanced materials, including tinted photochromic membranes and photovoltaic membranes.

In the foregoing specification, the invention has been described with reference to specific embodiments thereof. However, it will be evident that various modifications and changes can be made thereto without departing from the broader scope of the invention as set forth in the appended claims. Accordingly, the specification is to be regarded in an illustrative rather than a restrictive sense.

It is claimed:

1. A responsive façade system configured to control the transmission of light from a first side of the responsive façade system to a second side of the responsive façade system, the responsive façade system comprising:
a drive system;
a plurality of panels, wherein one or more of the plurality of panels is colored;
a sensor system that includes at least one light sensor configured to measure light intensity and output a responsive light sensor signal; and
a control system that includes a controller, wherein the controller is configured to send drive signals to the drive system to rotate the plurality of panels in response to the light sensor signal.

2. The responsive façade system of claim 1, wherein the drive system comprises:
a plurality of carriers, wherein on or more of the plurality of panels is connected to a corresponding one of the plurality of carriers; and
a plurality of drive motors, wherein each of the plurality of drive motors is connected to a corresponding one of the plurality of carriers.

3. The responsive façade system of claim 2, wherein the plurality of carriers comprise:
a plurality of horizontal carriers; and
a plurality of vertical carriers.

4. The responsive façade system of claim 3, wherein each horizontal carrier and each vertical carrier is independently rotatable.

5. The responsive façade system of claim 1, wherein the drive system comprises:
a plurality of drive motors, wherein each of the plurality of carriers is connected to a corresponding one of the plurality of panels and configured to rotate the corresponding one of the plurality of panels independently from the other of the plurality of panels.

6. The responsive façade system of claim 1, wherein the at least one light sensor is located on the responsive façade system.

7. The responsive façade system of claim 1, wherein the at least one light sensor is located remotely from the responsive façade system.

8. The responsive façade system of claim 1, wherein the at least one light sensor is configured to measure real-time sunlight data, and wherein the real-time sunlight data is used by the control system to instruct the drive system to rotate one or more of the plurality of panels into a position based on the real-time sunlight data.

9. The responsive façade system of claim 1, wherein at least some of the plurality of panels include photochromic coatings.

10. The responsive façade system of claim 1, wherein one or more of the plurality of panels has shape that approximates an octahedron.

11. The responsive façade system of claim 1, wherein one or more of the plurality of panels has a shape that approximates a rectangular prism.

12. The responsive façade system of claim 1, wherein one or more of the plurality of panels is constructed from a colored glass or polymeric material.

13. The responsive façade system of claim 1, wherein the drive system rotates each of the plurality of panels in response to variations in sunlight patterns, sunlight intensity, and sunlight direction.

14. A method of adjusting the intensity and quality of sunlight which enters an interior space, the method comprising the steps of:
providing a responsive façade system that includes a drive system and a plurality of colored panels rotatable by the drive system; and
rotating the plurality of colored panels to selectively block a portion of the sunlight that would otherwise enter the interior space.

15. The method of claim 14, wherein the step of rotating the plurality of panels further comprises:
measuring the sunlight that reaches the responsive façade system; and
automatically rotating the plurality of colored panels in response to the measurement of sunlight that reaches the responsive façade system.

16. The method of claim 15, wherein the step of automatically rotating the plurality of colored panels further comprises automatically rotating an individual panel independently from the other panels within the plurality of panels.

17. The method of claim 15, wherein the step of automatically rotating the plurality of colored panels further comprises automatically rotating a cluster of panels independently from the other panels within the plurality of panels.

18. A responsive façade system configured to control the transmission of light from a first side of the responsive façade system to a second side of the responsive façade system, the responsive façade system comprising:
a drive system;
a plurality of panels driven by the drive system, wherein each of the plurality of panels is colored;
a control system that includes a controller, wherein the controller is configured to send drive signals to the drive system to rotate the plurality of panels; and
a sensor system that includes at least one light sensor configured to measure real-time sunlight data, and wherein the real-time sunlight data is used by the control system to instruct the drive system to rotate one or more of the plurality of panels into a position based on the real-time sunlight data.

19. The responsive façade system of claim 18, wherein the drive system comprises:
a plurality of carriers, wherein on or more of the plurality of panels is connected to a corresponding one of the plurality of carriers; and
a plurality of drive motors, wherein each of the plurality of drive motors is connected to a corresponding one of the plurality of carriers.

20. The responsive façade system of claim 18, wherein the drive system comprises:
a plurality of drive motors, wherein each of the plurality of carriers is connected to a corresponding one of the plurality of panels and configured to rotate the corresponding one of the plurality of panels independently from the other of the plurality of panels.
